(19) United States
(12) Patent Application Publication
(10) Pub. No.: US 2022/0298645 A1
(43) Pub. Date: Sep. 22, 2022

(54) LASER INDUCED, FINE GRAINED, GAMMA PHASE SURFACE FOR NiCoCrAlY COATINGS PRIOR TO CERAMIC COAT

(71) Applicant: Raytheon Technologies Corporation, Farmington, CT (US)

(72) Inventors: Henry H. Thayer, Wethersfield, CT (US); Dmitri Novikov, Avon, CT (US); David Ulrich Furrer, Marlborough, CT (US)

(73) Assignee: Raytheon Technologies Corporation, Farmington, CT (US)

(21) Appl. No.: 17/569,102

(22) Filed: Jan. 5, 2022

Related U.S. Application Data
(63) Continuation-in-part of application No. 16/353,490, filed on Mar. 14, 2019, now abandoned.

(51) Int. Cl. C23C 28/00; C23C 16/02; C23C 14/02

(52) U.S. Cl. CPC C23C 28/3215; C23C 28/3455; C23C 16/0227; C23C 16/0272; C23C 14/022

(57) ABSTRACT

A process for forming a thermal barrier coating on a part comprising depositing an aluminum containing bond coat on the part, the bond coat comprising a surface; cleaning the surface to remove oxides and debris from the surface of the bond coat; forming a gamma phase layer proximate the surface of the bond coat; forming an aluminum oxide layer on the surface of the bond coat; and depositing a ceramic topcoat on the aluminum oxide layer on the bond coat.

### CROSS-REFERENCE TO RELATED APPLICATION

This application is a Continuation-In-Part of U.S. patent application Ser. No. 16/353,490, filed Mar. 14, 2019.

### BACKGROUND

The present disclosure is directed to a thermal barrier coating system for a component that is exposed to high temperatures, such as a gas turbine engine component (e.g. blades, vanes, etc.). More particularly, the present disclosure relates to the formation of a thermal barrier coating system and a method of forming a thermal barrier coating on a metal part that includes laser cleaning a surface of the metal part to produce a uniquely modified component surface that is optimized for subsequent development of a thermally grown oxide (TGO) and deposition of a thermal barrier coating that has an enhance durability and life. The present disclosure includes a combination of removal of undesirable oxides and residues from the surface of the part, creation of a substantially uniform composition surface layer optimized for TGO nucleation and growth, and the formation of a surface layer that is substantially smooth and flat as compared to surfaces produced by other processes, such as grit blasting or shot peening.

A gas turbine engine component, such as a blade tip, blade trailing edge, blade platform, blade airfoil, vane airfoil, vane trailing edge, or vane platform, is typically exposed to a high temperature and high stress environment. The high temperature environment may be especially problematic with a superalloy component. Namely, the high temperatures may cause the superalloy to oxidize, or weaken which then decreases the life of the component. In order to extend the life of the component, a thermal barrier coating system (TBC system) may be applied to the entire superalloy component or selective surfaces, such as surfaces of the superalloy component that are exposed to the high temperatures and other harsh operating conditions. A TBC system protects the underlying material (also generally called the “substrate”) and helps inhibit oxidation, corrosion, erosion, and other environmental damage to the substrate. Desirable properties of a TBC system include low thermal conductivity and strong adherence to the underlying substrate for system durability.

The TBC system includes a metallic bondcoat or oxidation resistant coating and a ceramic topcoat (i.e., a thermal barrier coating or TBC topcoat). The bondcoat is applied to the substrate and aids the growth of a thermally grown oxide (TGO) layer, which is typically alpha aluminum oxide, (Al₂O₃ or “alumina”). Specifically, prior to or during deposition of the TBC topcoat on the bondcoat, the exposed surface of the bondcoat can be oxidized to form the alumina TGO layer or scale. The TGO forms a strong bond to both the topcoat and the bondcoat, and as a result, the TGO layer helps the TBC topcoat adhere to the bondcoat. The bond between the TGO and the topcoat is typically stronger than the bond that would form directly between the TBC topcoat and the bondcoat. A continuous, uniform thickness TGO layer is desired to enable continuous bonding between the substrate, TGO and the topcoat. The ability to produce such a continuous TGO layer is beneficial.

In order for the TBC layer to adhere to the metallic bond coat (BC) (NiCoCrAlY for example), an oxide intermediate layer, a thermally grown oxide (TGO) is needed. Formation of aluminum oxide is known to be critical for oxidation protection during component operation. Others [Gorman—U.S. Pat. No. 7,413,778] have taught that modifying a bond coat by adding supplemental aluminum concentrations on the surface by an aluminizing process is beneficial.

Bond coat alloy in equilibrium consists of aluminum (Al) poor phase (“gamma” phase, face centered cubic (fcc) crystal structure) and Al rich phase (“beta” phase, body centered cubic (bcc) crystal structure) with a size scale of each individual phase being similar and on the order of 2-5 microns. This arrangement of phases with different aluminum concentrations on the surface of a bond coat with these spatial length scales results in variations in TGO formation, thickness and subsequent growth on the same surface spatial length scale. This means that TGO can readily form TGO in one area where there is Beta phase and to a much less extent in areas where there is Gamma phase. This initial variation in TGO formation, thickness and subsequent growth rate due to local differences in aluminum concentration in the bond coat lead to local variations in bonding effectiveness between the substrate, TGO layer and the topcoat. The surface variations in TGO formation and subsequent growth rate result in continued and increased differences in TGO thickness that result in an effective TGO roughness and increase in interfacial stresses during thermal loading, which can lead to pre-mature interface failure.

It should be noted that self-diffusion coefficient in bcc “beta” phase is by order of magnitude higher than the one in fcc “gamma” phase due to its lower packing factor and lower coordination number.

Meehan—U.S. Pat. No. 9,683,281 does not teach the formation of a gamma layer proximate the surface, and Stamm—U.S. Pat. No. 6,610,419 defines a technology including an inner MCrAlY (bond coating) layer and “having a second MCrAlY alloy, which is bonded to the inner layer.”

Although the TGO is needed to bond the TBC to the metallic coat, the TGO continues to grow as the engine runs. The slight mismatch in volume between the TGO and TBC causes a build-up of stress between them that eventually causes the coating to fail. Therefore, it is important to have the thinnest and most uniform TGO possible at the start of the process, slow the growth of the TGO, and maintain a smooth uniform TGO thickness during engine operation conditions.

### SUMMARY

In accordance with the present disclosure, there is provided a process for forming a thermal barrier coating system on a part comprising depositing an aluminum containing bond coat on the part, the bond coat comprising a surface; cleaning the surface to remove oxides and debris from the surface of the bond coat and producing a smooth and flat surface; forming a gamma phase or near-gamma phase layer proximate the surface of the bond coat; forming an aluminum oxide layer on the surface of the bond coat; and depositing a ceramic topcoat on the aluminum oxide layer on the bond coat.

In another and alternative embodiment, the bond coat is a conventional alloy with no alterations in bulk chemistry to produce a new chemistry and phases on the surface layer after modification with an energy beam.

In another and alternative embodiment, the bond coat bulk chemistry is uniformly optimized to produce a unique chemistry of the modified surface layer after modification with an energy beam.

In another and alternative embodiment, the cleaning comprises exposing the surface to an energy beam focused on the surface of the bond coat and forming a liquid from the bond coat proximate the surface.

In another and alternative embodiment, the process further comprises rapidly cooling the liquid into the gamma phase layer, and forming an alpha aluminum oxide proximate the surface.

In another and alternative embodiment, the energy beam produces high intensity, short duration energy beam pulses.

In another and alternative embodiment, the process further comprises inhibiting a non-alpha aluminum oxide layer from growing responsive to the gamma phase layer proximate the surface.

In another and alternative embodiment, the process further comprises distributing the aluminum in the bond coat uniformly, so that the alpha aluminum oxide layer is even in thickness, continuous, smooth and flat and has reduced internal stresses after formation and during use.

In another and alternative embodiment, the gamma phase layer proximate the surface comprises a supersaturated aluminum content. Supersaturation is defined as the concentration of one or more elements are higher than thermodynamically allowed in equilibrium at the given temperature. Gamma phase supersaturation with aluminum at room temperature can be produced by dissolving the beta phase at elevated temperature and increasing the aluminum concentration of the gamma phase to that of the equilibrium concentration at the elevated temperature. Cooling the gamma phase at a rate sufficient to suppress some or all nucleation and growth of beta phase will result in complete or partial supersaturation. If some beta phase re-precipitates then the amount of aluminum supersaturation will be reduced in the gamma phase while producing small and uniformly spaced beta precipitates. Gamma-phase supersaturation can also be produced by heating the bond coat material to the liquid phase field and again cooling at rate sufficiently high to suppress the kinetics of beta phase formation and required partitioning of aluminum between the gamma and beta phases by diffusion. FIG. 4 shows the equilibrium phase diagram for a typical bond coat material. This figure shows that as you heat the bond coat material up from 500 C to 800 C the percentage of gamma phase present goes from 15% to 65%. Further heating to 1325 C results in further growth of the gamma phase to 85%. Equilibrium phase diagrams teach that conservation of mass the percentage of aluminum in bond coat must partition or segregate to the gamma phase during heating as the percentage of other phases decrease. The measured room temperature equilibrium concentration of aluminum is gamma phase is: ˜4.5% and for the beta phase is: ˜18%. As the percentage of beta decreases and the percentage of gamma increases during heating the aluminum concentration in the gamma phase must increase. The modified bond coat layer produced by the disclosed technology is comprised of gamma phase with a measured aluminum concentration of ˜10%. This shows that the modified bond coat layer is comprised of gamma phase with a measured level of supersaturation.

In another alternative embodiment, the surface is comprised primarily of gamma phase and very small precipitates of beta phase on the order of <1 um that acts as a single phase and uniform aluminum reservoir from an aluminum diffusivity perspective.

In another and alternative embodiment, the process further comprises growing an initial alpha-alumina scale during the cleaning step.

In another and alternative embodiment, the gamma phase layer comprises a thickness of about 1.5 microns.

In another and alternative embodiment, the gamma phase layer proximate the surface of the bond coat is an aluminum diffusion inhibitor.

In another and alternate embodiment, the modified surface layer proximate the surface of the bond coat contains elements that add to the TGO and alter the diffusivity of aluminum and/or oxygen to control the growth rate of the TGO.

In another and alternative embodiment, the gamma phase layer impedes fast aluminum oxidation at the surface.

In another and alternative embodiment, the gamma phase layer allows for a very thin initial alpha-alumina scale (layer) to grow during the cleaning step.

It is now known that uniform chemistry bond coats can be modified on the surface to produce the desired level of aluminum concentration and distribution without the need for supplemental aluminum addition to the coat surface.

Similarly, a locally smooth and flat substrate surface enables TGO to be formed that is locally smooth and flat that can mitigate local stress concentrations from sharp features such as notches or other discontinuities (valleys or asperities), which reduces thermal stresses which often lead to cracking and spallation of topcoat regions. The TGO also acts as an oxidation resistant layer, or an “oxidation barrier”, to help protect the underlying substrate from damage due to oxidation.

Other details of the process are set forth in the following detailed description and the accompanying drawings wherein like reference numerals depict like elements.

### BRIEF DESCRIPTION OF THE DRAWINGS

FIG. 1 is a perspective view of a turbine blade.

FIG. 2 is a cross-sectional view of the turbine blade of FIG. 1 where a section has been taken at line 2-2 (shown in FIG. 1) and show a thermal barrier coating system overlying the airfoil of the turbine blade.

FIG. 3 is an exemplary cleaning process.

FIG. 4 is a phase diagram of an exemplary bond coat as a function of temperature.

FIG. 5 shows a schematic of the traditional grit blasting process 100 in comparison to the disclosed process of FIG. 3.

FIG. 6 depicts images of surface roughness from conventional and exemplary surface cleaning and modification process.

FIG. 7 shows a comparison of actual traditional (grit blast) TBC System manufacturing process and the exemplary bond coat cleaning and modification process.

FIG. 8 shows New Figure that shows the TBC system. Base Beta and Gamma phases in Bond Coat. Single Gamma Phase layer on surface of Bond Coat. Smooth and continuous Bond Coat and TGO layer.

### DETAILED DESCRIPTION

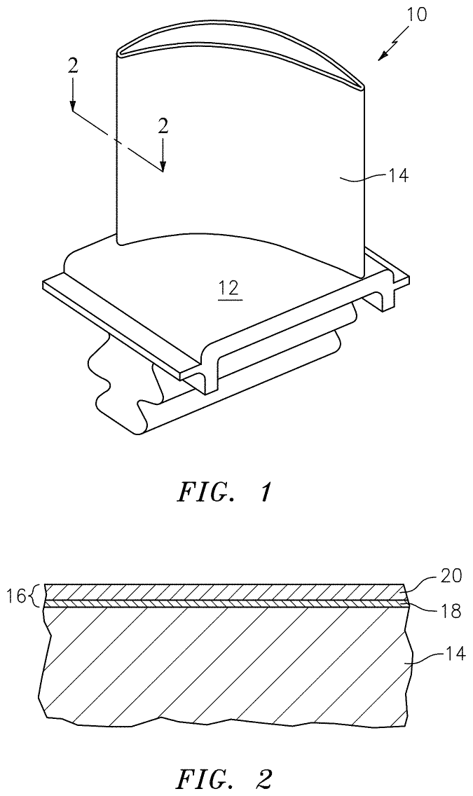

FIG. 1 is a perspective view of turbine blade 10 of a gas turbine engine. Turbine blade 10 includes platform 12 and airfoil 14. Airfoil 14 of turbine blade 10 may be formed of a nickel based, cobalt based, iron based superalloy, or mixtures thereof or a titanium alloy. Turbine blade 10 is exposed to high temperatures and high pressures during operation of the gas turbine engine. In order to extend the life of turbine blade 10 and protect it from high stress and temperature operating conditions and the potential for oxidation and corrosion, a thermal barrier coating (TBC) system (shown in FIG. 2) is applied over airfoil 14 and platform 12 of turbine blade 10.

The exact placement of the TBC system depends on many factors, including the type of turbine blade 10 employed and the areas of turbine blade 10 exposed to the most stressful conditions. For example, in alternate embodiments, a TBC may be applied over a part of the outer surface of airfoil 14 rather than over the entire surface of airfoil 14. Airfoil 14 may include cooling holes leading from internal cooling passages to the outer surface of airfoil 14, and the system 16 may also be applied to the surface of the cooling holes.

FIG. 2 is a sectional view of turbine blade 10, where a section is taken from line 2-2 in FIG. 1. TBC system 16 is applied to an exterior surface of airfoil 14 and platform 12.

TBC system 16 may include bondcoat 18 and ceramic layer 20. Bond coat 18 overlays and bonds to airfoil 14 and platform 12 while ceramic layer 20 overlays and bonds to the thermally grown oxide (TGO) on the bond coat 18. In the embodiment shown in FIG. 2, bond coat 18 may be applied to airfoil 14 and platform 12 at a thickness ranging from about 0.5 mils (0.0127 mm) to about 10 mils (0.254 mm). Ceramic layer 20 may be any thermal barrier coating (or “topcoat”) that is suitable for use on alumina forming bond coats and/or alloys. Non-limiting examples include zirconia stabilized with yttria (Y₂O₃), gadolinia (Gd₃O₃), ceria (CeO₂), scandia (Sc₂O₃), and other oxides known in the art. Ceramic layer 20 may be applied by electron beam physical vapor deposition (EBPVD) or by plasma spray. Ceramic layer 20 may be deposited in thickness sufficient enough to provide the required thermal protection for bondcoat 18 and substrate 10.

Bond coat 18 may be a MCrAlY coating where M may be Ni, Co, Fe, Pt, Ni-base alloy, Co-base alloy, Fe-base alloy or mixtures thereof. In an embodiment, M may include Hf or Si or mixtures thereof. In an exemplary embodiment, the bond coat 18 can comprise NiCoCrAlY. Bond coat 18 may be applied to airfoil 14 and platform 12 by any suitable technique including, but not limited to, thermal spray processes such as low pressure plasma spray (LPPS) deposition and high velocity oxyfuel (HVOF) deposition, physical vapor deposition such as cathodic arc deposition or chemical vapor deposition, and the like. In an embodiment, bond coat 18 may be an aluminide bondcoat formed by techniques such as pack cementation, chemical vapor deposition, and others followed by appropriate diffusion heat treatments. In another and alternate embodiment, special elements (e.g. Hf, Pt, Y, etc) can be added to the top surface of the bond coat prior to the surface modification process so these special elements are incorporated in the modified surface layer of the bond coat and subsequently into the TGO.

Critical features that differentiate this disclosed technology from prior art include the: 1. The smoothness of the bond coat top surface 32, the flatness of bond coat top surface 32, the chemical uniformity of bond coat modified surface layer 44 and the thickness uniformity of the modified surface layer 44 and the TGO 46.

For the purposes of this disclosure, smoothness is defined as the typical range of the depth of surface valleys or height of asperities. The defined technology provides a typical bond coat top surface 32 smoothness of 0.1-0.2 microns, whereas traditional methods produce smoothness values on the order of 1-2 microns.

For the purpose of this disclosure, flatness of defined as the number of discreet valleys or asperities per unit length. The defined technology provides for a typical surface flatness for the modified bond coat surface layer 44 of 0.5/micron, whereas traditional methods produce flatness values of >5/micron.

For the purpose of this disclosure, chemical uniformity is defined by the distance between the regions of maximum and minimum chemical element concentration. The defined technology produces chemical uniformity of the modified bond coat surface layer of <1 micron, whereas traditional methods where bond coat microstructures contain equilibrium concentrations of beta and gamma phases produces chemical uniformity on the order of 2-5 microns.

For the purposes of this disclosure, thickness uniformity is defined as the range of thickness of a coating or layer. The defined technology produces a thickness uniformity of bond coat modified surface layer of <0.5 microns but typically <0.1 microns. The defined technology produces an initial thickness uniformity for the TGO of <0.1 microns, whereas the traditional processes initial TGO thickness uniformity >1.0 micron.

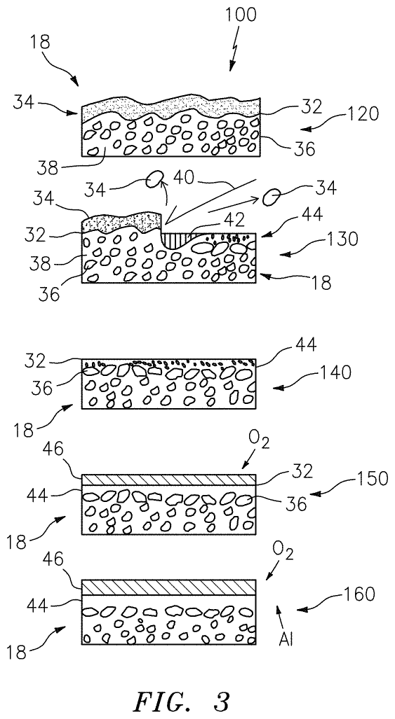

The bond coat modification process (process 100) can be understood by referring also to FIG. 3. At an initial state 120, the bondcoat 18 includes a surface 32 covered with debris/contaminant materials 34, such as oils, oxides and the like. Within the bond coat 18, a combination of large scale beta phase bcc structure 36 and gamma phase fcc structure 38 is shown distributed throughout the bond coat 18.

Others [Meehan—U.S. Pat. No. 9,683,281] have taught that cleaning surface with a laser is optional, though new understanding has shown that complete cleaning of bond coat surfaces is required to eliminate surface geometry variation and variations in surface chemistry that can lead to non-uniform TGO formation and growth.

At step 130 cleaning and structural refinement takes place at and near the surface 32 of the bond coat 18. The cleaning is done at high temperature and at an atmospheric pressure. In an exemplary embodiment, the cleaning temperature can be above 1350 degrees C., the point at which the NiCoCrAlY liquefies and at different surrounding pressures. An energy beam 40 is utilized to remove the debris/contaminants 34 through ablation and thermal spallation while also melting the bond coat 18 proximate the surface 32, forming a liquid 42 from the bond coat 18 material. The liquid 42 subsequently rapidly cools down into a fine grained layer 44. The grain refinement is achieved by very rapid melting and re-solidification of the bond coat 18 material at the surface 32 under very high intensity, short duration energy beam pulses. In an exemplary embodiment, the energy beam 40 can utilize a 50-100 nano-second pulse duration at 5-50 J/cm\hat{ }2. The local surface 32 heating above the predetermined temperature, such as 1350 degrees Centigrade, can create the fine grained predominantly gamma phase layer 44 proximate the surface 32. Raising the temperature this way causes the metal right at the surface to liquefy very quickly, and re-solidify very quickly providing the desired fine grain structure and spatially uniform distribution of constituent elements (e.g. aluminum).

The energy beam 40 can include a laser. The laser can include an yttrium aluminum garnet laser, ultraviolet, eximer, or carbon dioxide, fiber, or disc laser. The laser can have a power range up to about 1000 watts.

The surface environment during the cleaning portion 130, can include air, inert gas, water, or combinations thereof.

In an exemplary embodiment, a laser based cleaning system for removing contaminants from the surface 32 may include: a laser 40 capable of removing the oxide layer and producing an aluminum oxide layer on the substrate surface 32; an optical system capable of focusing the laser at the oxide layer; and a scanning system capable of directing the focused laser beam over the surface 32 to remove contaminants to produce the gamma phase layer 44 on the substrate 32. The exemplary embodiment results in surface cleanliness markers of surface carbon and oxygen to be reduced from 14% and 11% to 3% and 0% respectively.

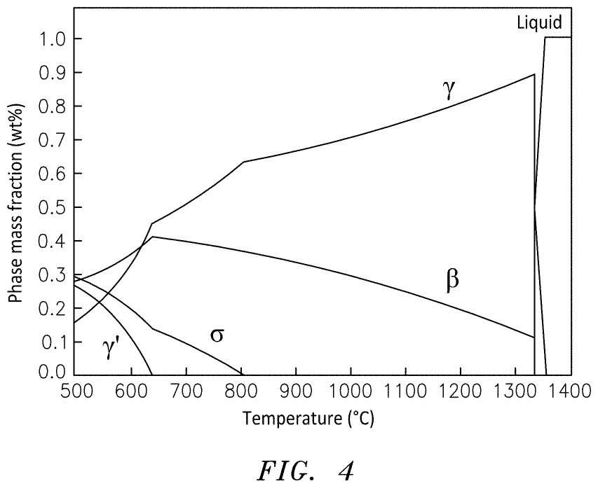

In an exemplary embodiment, the Al-rich gamma phase layer 44 can be about 0.5 microns. In an exemplary embodiment the gamma phase layer 44 can range from about 0.25 microns to about 0.75 microns. In another exemplary embodiment, the gamma phase layer 44 can be about 1.5 microns thick. The thickness of the layer 44 can be controlled by the amount of energy beam applied power to the surface 32. In an exemplary embodiment, the energy beam 40 applied power can range from about 500 Watts to about 1000 Watts. In an exemplary embodiment, the surface 32 can be heated to about 1350 degrees C. The surface 32 can be heated to temperatures from about 1350 degrees C. possibly much hotter, but not so hot as to start rapidly boiling off the Aluminum. At the higher temperatures, as can be seen at FIG. 4, the bond coat 18 is converted predominantly to gamma phase and/or liquid.

The noted surface modification process with the controlled energy beam is also structurally refined to produce a smooth and flat surface. The exemplary embodiment provides sufficient energy to result in the desired surface melting, phase modification and chemical homogenization (chemical uniformity) of the surface layer and substantially reduce the size and frequency of surface discontinuities that have resulted from bond coat production and processing.

At 140 it can be seen that after cleaning and structural refinement, the bond coat 18 includes the gamma phase layer 44 with a smooth surface 32. The elements proximate the surface 32 of the metallic bond coat 18 tend to be Ni and Al. The molten alloy 42 freezes first at the location where it is in contact with the bulk of the solid bond coat 18 and freezes last where the molten alloy 42 is in contact with air or process gases. Thus, the disclosed process promotes gamma-alumina formation proximate the surface 32. Under ambient conditions, the gamma phase normally has lower Al content than the beta phase. However, because of the rapid melting and refreezing caused by the energy beam 40, all of the dissolved Al is still present, so the modified predominantly gamma phase layer 44 is Al rich, or supersaturated with Al. Because the gamma phase is supersaturated with Al (i.e. it wants to get rid of Al) the gamma phase layer 44 has ability to create a dense initial alpha-alumina layer of TGO and avoid the non-alpha phase aluminum.

The layer 44 is Al supersaturated which can be beneficial for the next step 150 of forming the aluminum oxide layer (TGO) 46 on the surface 32. The uniform spatially distributed elements in the modified surface layer results in a continuous and uniform aluminum oxide layer. The extremely fine grain structure 44 distributes the aluminum in the bond coat 18 very uniformly, so that the thermally grown oxide (TGO) 46 is even and has fewer internal stresses.

At 160, it can be seen that once the thermally grown oxide 46 is formed, the TGO 46 will be inhibited from growing rapidly, and will grow slowly as compared to a surface that was not treated by the disclosed process. The gamma phase 44 proximate the surface is reduced in aluminum content and has poor diffusivity properties for aluminum. The slower TGO 46 growth will result in good adhesion between the TBC 20 and the metallic bond coat 18. This also provides the benefit of longer life adhesion of the TBC 20, because the TGO 46 thickness is smaller and the stresses between the TGO 46 and TBC 20 will grow more slowly. The uniform gamma like fcc phase has an order of magnitude lower self-diffusion coefficient that the beta bcc phase material. The gamma phase 44 impedes fast Al oxidation at the surface 32, and allows for a very thin initial alpha-alumina scale to grow during the disclosed laser cleaning process. The rapid cooling and formation of the gamma phase layer inhibits a non-alpha aluminum oxide layer from growing responsive to said gamma phase layer proximate said surface. The non-alpha aluminum oxides can include aluminum oxide in other phases, including the cubic γ and η phases, the monoclinic θ phase, the hexagonal χ phase, the orthorhombic κ phase and the δ phase that can be tetragonal or orthorhombic. The aluminum supersaturation ensures that aluminum oxides are preferentially created proximate the surface 32. During subsequent TGO 46 growth in an EB-PVD chamber that initial alpha-alumina creates conditions for preferential alpha-alumina growth, which is less prone to further oxygen diffusion that causes TGO growth during part service life. TBC spallation happens when the TGO thickness reaches a certain value. The disclosed process provides for the initial TGO thickness and TGO growth rate coefficient to be smaller. The TGO growth coefficient for laser cleaned sample is about 2 times smaller than that for a grit blasted one.

The modified surface layer 44 can contain elements that also alloy or mix with the aluminum oxide. These added elements can be within the entire bond coat chemistry, or an alternate process could be utilized that allows for local application of special elements (e.g. Hf, Y, Pt, etc.) that when added to aluminum oxide result in greatly reduced aluminum and oxygen diffusivity in the aluminum oxide which controls the rate of growth and subsequently increases TBC System life through mitigating internal stresses that form during excessive TGO growth. The special elements can be added to the surface of the bond coat before surface modification or after an initial surface cleaning process, which is subsequently followed by another surface modification process. The special elements could be added by plating, vapor deposition, thermal spraying or other types of processes to add chemical elements to the surface of a bond coat.

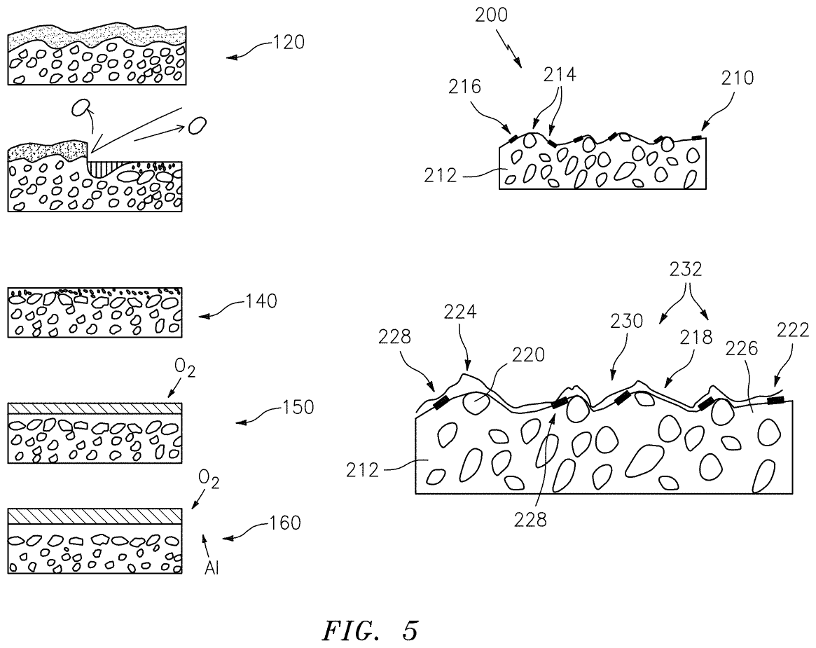

FIG. 5 shows a schematic of the traditional grit blasting process 200 in comparison to the disclosed process of FIG. 3. In FIG. 5, the schematic shows where a surface 210 of the bond coat 212 remains substantially rough, not fully clean and where both large scale (2-5 um) grains of both beta and gamma phase 214 are present at the surface 210. These specific features are non-ideal and are specifically elements that are addressed with the disclosed embodiments. The remaining debris/contaminants 216 on the grit blast surface impede the formation, growth and bonding of TGO in these locations. The rough grit blast surface 210 results in a rough TGO surface 218 that results in internal stresses during manufacture and use that can lead to coating failure and spallation. Similarly, the grit blast surface 210 contains beta grains 220 on the surface that provide for a large concentration of aluminum and gamma grains 222 that provide for reduced aluminum. These spatial variations in aluminum concentration result in variations in local TGO formation and growth. The TGO growth rate 224 adjacent to beta grains grow faster while the TGO adjacent to gamma grains 226 grows slower. There can be TGO discontinuity 228 adjacent contamination 216. The location variation 232 in TGO growth rate results in non-uniform TGO thickness 230, increased TGO surface roughness and increase internal stresses that can lead to coating failure and spallation. The embodied disclosure shown at FIG. 3 mitigates these features and provides for increased TBC coating capabilities in the form of increased durability and component life.

The disclosed process shown in FIG. 3 relies upon surface chemical/phase composition modifications of the bond coat 18. In an exemplary embodiment, further protection can include adding other alloying elements to the bond coat surface 32, such as Pt, to further impeded the TGO growth.

Others have taught that the use of energy beams and lasers can be used on bond coat surfaces. The formation of a unique chemistry gamma layer proximate the surface of a bond coat distinguishes from the past teaching.

The current disclosure contains a single gamma-phase layer on top of the original bond coating 18, which is produced from the original bond coating 18 and not a separate layer which is bonded to the initial inner layer of MCrAlY (bond coat).)

The current disclosure defines the requirement to heat the surface of the bond coat rapidly to a high temperature where >65-90% gamma phase or liquid exists (˜800 C to ˜1350 C) as defined in the phase equilibrium diagram of FIG. 4. It is critical that rapid heating is used to provide controlled heating of a specific volume (thickness) of the bond coat surface 32 to the defined high temperature. The requirement to heat the controlled volume (thickness) of the bond coat surface 32 requires a specific energy source value and energy source application time duration. In addition to heating the controlled surface volume to the required phase field, the energy source value and application time duration must be controlled to produce a unique and controlled heat flux that produces a specific thickness of modified bond coat as a new surface layer and required cooling rate to produce the phase structure and chemical distribution in the modified bond coat surface layer by suppressing the kinetics of second phase nucleation or growth. Too high of energy or too long of duration of energy application will produce boiling, excessive loss of volatile elements that would change the average chemistry of the modified bond coat material and a very large volume (thickness) of bond coat 18 that is modified. It is required that only a controlled volume (thickness) of bond coat 18 is modified to produce the flat and smooth surface geometry and a modified layer chemistry and phase constituents to provide for the unique, continuous and uniform thickness TGO. Too large of a modified layer will reduce the function of the base bond coat material and too thin of a modified bond coat surface layer negate the ability to eliminate surface irregularities from prior processing of the bond coat.

The thickness of the modified bond coat layer is important relative to provide a uniform chemistry layer with an optimal thickness to provide for an aluminum reservoir for alpha-aluminum oxide formation and for control of aluminum diffusion between the aluminum oxide layer and the base multi-phase bond coating. The target modified bond coat 18 thickness is 1.5 microns to optimize for bond coat capability, surface geometry and TGO formation capability attributes. Stamm—U.S. Pat. No. 6,610,419 requires a 5-50 um or 5-20 um thickness of an outer layer of gamma-phase.

An additional method to control the temperature and volume (thickness) of bond coat 18 that is modified beyond the energy level of the beam and the time duration of the energy beam application, use of a pulsed application of the energy beam can be utilized and is an integral part of this disclosure.

Inhibiting a non-alpha aluminum oxide layer from growing is a critical feature of the disclosure. The diffusion control of aluminum oxide formation that results from the controlled chemistry, single-phase or near single-phase gamma layer inhibits the formation of other aluminum oxide phased other than alpha-aluminum oxide. The thermodynamic activity (concentration) of aluminum in combination with the diffusion rate of aluminum in the gamma phase provides for the unique capabilities of this new technology.

The surface 32 of the modified bond coat layer 18 and associated aluminum oxide produced on top by the new technology are critically flat and smooth and not previously defined or taught by others. Notched features result in a rough oxide layer that produces high stress and limited coating system life. Surfaces produced by Meehan-9683281 are not plainer nor smooth as defined by the current disclosure. The creation of the beneficial geometric features of being smooth and flat are critical elements of the technology to enable the defined advantages of reduced internal and evolving stresses from operational thermal loading and continued growth of the TGO layer.

An additional concept can be to locally add special elements (e.g. Hf, Pt, Y, etc.) to the surface 32 of the bond coat 18 prior to modification so these special elements are incorporated in the modified surface layer and subsequently into and modify the growth behavior of the TGO.

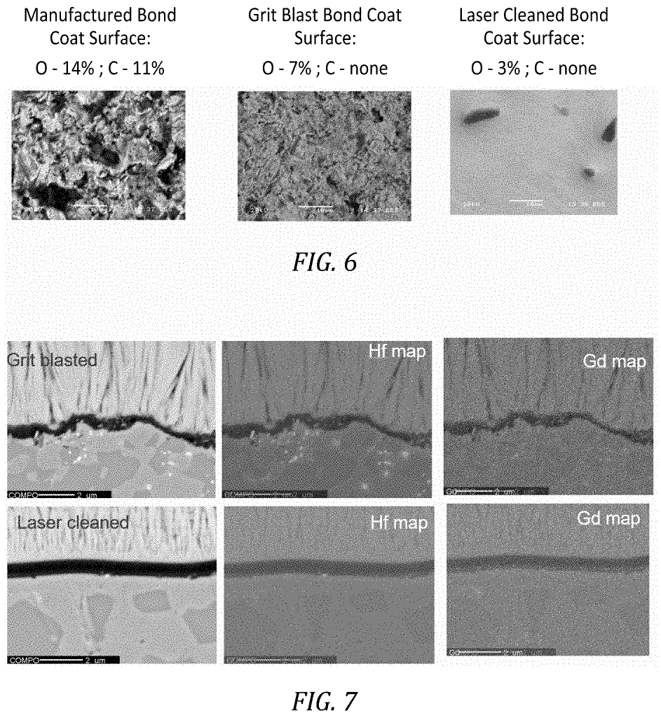

Referring also to FIG. 6, images of the surface roughness of the coating are shown. The image on the left shows a surface of the coating after manufacture. The image in the center shows a surface of the coating after a grit blasting process. The image on the right shows the surface of the coating after the exemplary process. Demonstration of surface roughness from conventional and new surface cleaning and modification process.

Referring also to FIG. 7, shows a comparison of actual traditional (grit blast) TBC System manufacturing process and the exemplary bond coat cleaning and modification process.

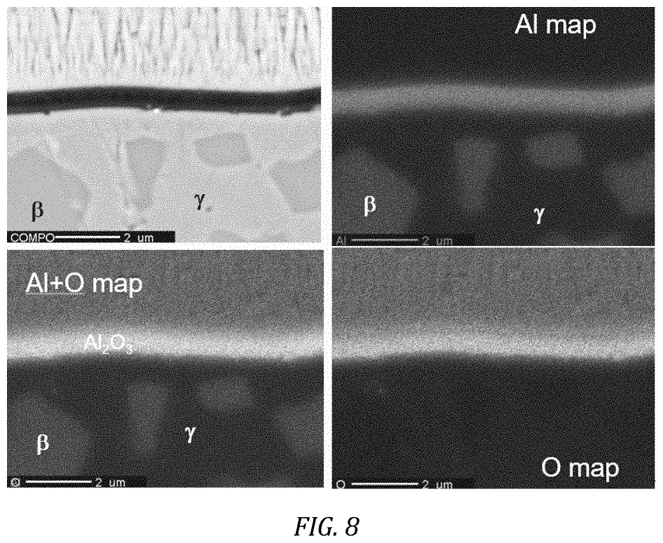

Referring also to FIG. 8, shows the exemplary coating system. Base Beta and Gamma phases in Bond Coat. Single Gamma Phase layer on surface of Bond Coat. Smooth and continuous Bond Coat and TGO layer.

The technical benefits of utilizing the disclosed process includes optimized surface chemistry for optimal TGO growth.

Another technical advantage of the disclosed process is the development of a smooth surface 32 without steps and ledges that mitigates geometric stress build-up.

Another technical advantage of the disclosed process is that surface treated material is given a diffusion barrier and controller for aluminum so that the TGO starts and continues to grow uniformly with a smooth, non-stepped geometry.

Another technical advantage of the disclosed process is that surface treating with a laser or other energy source (like e-beam) is a preferred approach.

Another technical advantage of the disclosed process can include adding supplemental elements to the surface by pre-coating (vapor deposition, sputtering, etc.) followed by laser processing that can also provide optimal surface material for TGO growth and subsequent diffusion barrier/control.

There has been provided a bond coat modification process. While the process has been described in the context of specific embodiments thereof, other unforeseen alternatives, modifications, and variations may become apparent to those skilled in the art having read the foregoing description. Accordingly, it is intended to embrace those alternatives, modifications, and variations which fall within the broad scope of the appended claims.

What is claimed is:

1. A process for modifying a surface layer of a bond coat on a substrate of a part comprising:
providing an aluminum containing NiCoCrAlY bond coat on the substrate of the part, said bond coat comprising a surface;
cleaning said surface to remove oxides and debris from the surface of the bond coat, said cleaning comprises exposing the surface to an energy beam having an applied power that ranges from about 500 Watts to about 1000 Watts focused on the surface of the bond coat and converting a beta phase into a gamma phase in the bond coat proximate the surface above a temperature of 1350 degrees Centigrade, said surface comprising a smooth surface without steps and ledges configured to mitigate geometric stress build-up;
forming a gamma phase layer proximate the surface of the bond coat, by cooling the bond coat in order to form said gamma phase layer, the gamma phase layer ranging from 0.25 microns to 0.75 microns, wherein said gamma phase layer proximate the surface comprises a supersaturated aluminum content comprising 10 wt % aluminum;
forming an alpha aluminum oxide layer on said surface of said bond coat, distributing the aluminum in the bond coat uniformly, so that the alpha aluminum oxide layer is even.

2. The process according to claim 1, wherein said energy beam produces high intensity, short duration energy beam pulses, said the energy beam including a 50-100 nano-second pulse duration at 5-50 J/cm\hat{ }2.

3. The process according to claim 1, further comprising: inhibiting a non-alpha aluminum oxide layer from growing responsive to said gamma phase layer proximate said surface.

4. The process according to claim 1, wherein said gamma phase layer proximate the surface of the bond coat is an aluminum diffusion inhibitor.

5. The process according to claim 1, wherein the gamma phase layer comprises a thickness of about 1.5 microns.

6. The process according to claim 1, wherein said gamma phase layer provides uniform aluminum oxide formation at the surface.

7. The process according to claim 1, wherein said gamma phase layer impedes fast aluminum oxidation at the surface.

8. The process according to claim 1, wherein the gamma phase layer allows for a very thin initial alpha-alumina scale to grow during said cleaning step.

9. The process according to claim 1, further comprising:
adding at least one alloying element to the bond coat surface.

10. A process for modifying a surface of a substrate of a part comprising:
providing an aluminum containing NiCoCrAlY bond coat on the substrate of the part, said bond coat substrate comprising a surface;
cleaning said surface to remove oxides and debris from the surface of the bond coat, said cleaning comprises exposing the surface to an energy beam having an applied power that ranges from about 500 Watts to about 1000 Watts focused on the surface of the bond coat, wherein said energy beam produces high intensity, short duration energy beam pulses, said the energy beam including a 50-100 nano-second pulse duration at 5-50 J/cm\hat{ }2;
converting a multiple phase structure into a single phase structure in the bond coat proximate the surface above a temperature of 1350 degrees Centigrade, said surface comprising a smooth surface without steps and ledges configured to mitigate geometric stress build-up;
forming a single phase layer proximate the surface of the bond coat, by cooling the bond coat in order to form said single phase layer, the single phase layer ranging from 0.25 microns to 0.75 microns, wherein said single phase layer proximate the surface comprises a supersaturated structure; and
forming an aluminum oxide layer on said surface of said substrate, distributing aluminum in the bond coat surface uniformly, so that the aluminum oxide layer is continuous and of even thickness.

11. The process of claim 10 wherein said multiple phase structure comprises a beta phase and a gamma phase.

12. The process of claim 10 wherein said single phase structure comprises a gamma phase in the bond coat.

13. The process of claim 10 wherein said supersaturated structure comprises an aluminum content comprising 10 wt % aluminum.

14. The process of claim 10 wherein said distributing chemical elements comprises distributing aluminum.
